(19) United States
(12) Patent Application Publication
(10) Pub. No.: US 2024/0363407 A1
(43) Pub. Date: Oct. 31, 2024

(54) LOW-ENERGY UNDERLAYER FOR ROOM TEMPERATURE PHYSICAL VAPOR DEPOSITION OF ELECTRICALLY CONDUCTIVE FEATURES

(71) Applicant: Applied Materials, Inc., Santa Clara, CA (US)

(72) Inventors: Jie ZHANG, Sunnyvale, CA (US); Liqi WU, San Jose, CA (US); Cory LAFOLLETT, Santa Clara, CA (US); Tsung-Han YANG, San Jose, CA (US); Wei WENG, Santa Clara, CA (US); Qihao ZHU, Sunnyvale, CA (US); Jiang LU, Milpitas, CA (US); Rongjun WANG, Dublin, CA (US); Xianmin TANG, San Jose, CA (US)

(73) Assignee: Applied Materials, Inc., Santa Clara, CA (US)

(21) Appl. No.: 18/309,669

(22) Filed: Apr. 28, 2023

(51) Int. Cl. H01L 21/768; H01L 21/02

(52) U.S. Cl. CPC H01L 21/76877; H01L 21/02274; H01L 21/76843; H01L 21/76865; H01L 21/76883

(57) ABSTRACT

Embodiments of the present disclosure generally relate to a method for forming an electrically conductive feature on a substrate. In one embodiment, the method includes forming a first conductive layer via physical vapor deposition (PVD) in an opening of a substrate. The first conductive layer has a thickness of less than 20 angstroms. The method further includes forming a second conductive layer via PVD on the first conductive layer. The first conductive layer and the second conductive layer are formed at a temperature of less than 50° C. The method further includes annealing at least a portion of the first conductive layer and the second conductive layer.

### BACKGROUND

### Field

Embodiments of the present disclosure generally relate to physical vapor deposition (PVD) film formation on substrates in an electronic device fabrication process, and more particularly, to apparatus and methods for depositing one or more film layers in features formed on a substrate.

### Description of the Related Art

Conductive features grown via physical vapor deposition (PVD) techniques, such as tungsten capping and liner processes, are foundational to minimizing contact resistance in middle-of-line (MOL) process steps. Existing tungsten capping and liner processes include PVD tungsten deposition, tungsten wet etch removal, and chemical vapor deposition (CVD) deposition of tungsten to either selectively deposit tungsten bottom-up, or to conformally fill a MOL structure, such as a trench associated with a gate, a contact pad, a conductive line, via, etc. Achieving high bottom coverage with minimal overhang is a prerequisite to achieving good gap fill for a bottom-up deposition approach. Existing approaches, however, have a number of drawbacks.

For example, sputtering of high-aspect ratio features (e.g., trenches) commonly results in a disproportionate amount of material accumulating on the edges of the feature into which the material is being deposited. This accumulation of excess material creates overhang, which results in bottom coverage reduction or pinch-off. Additionally, PVD deposition of conductive materials, such as tungsten, commonly results in penetration of the material into the substrate onto which it is deposited. Consequently, after pullback (or a similar etching process), a portion of the conductive material remains intermixed with the substrate, degrading the electrical characteristics of conductive features formed on/in the substrate.

Accordingly, improved techniques for forming conductive features via PVD processes are needed.

### SUMMARY

Embodiments of the present disclosure generally relate to a method for forming an electrically conductive feature on a substrate. In one embodiment, the method includes forming a first conductive layer via physical vapor deposition (PVD) in an opening of a substrate. The first conductive layer has a thickness of less than 20 angstroms. The method further includes forming a second conductive layer via PVD on the first conductive layer. The first conductive layer and the second conductive layer are formed at a temperature of less than 50° C. The method further includes annealing at least a portion of the first conductive layer and the second conductive layer.

In another embodiment, a method includes forming a first conductive layer via physical vapor deposition (PVD) in an opening of a substrate. The first conductive layer has a thickness of less than 20 angstroms. The method further includes forming a second conductive layer via PVD on the first conductive layer. The second conductive layer has a thickness of greater than 20 angstroms, and the first conductive layer and the second conductive layer are formed at a temperature of less than 50° C.

In another embodiment, a method includes forming a first conductive layer via physical vapor deposition (PVD) in an opening of a substrate. The first conductive layer has a thickness of less than 20 angstroms. The method further includes forming a second conductive layer via PVD on the first conductive layer. The first conductive layer and the second conductive layer are formed at a temperature of less than 50° C. The method further includes depositing a third conductive layer via chemical vapor deposition (CVD) on the second conductive layer.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2 is a cross-sectional view of a chamber, according to embodiments described herein.

FIG. 3 depicts a flow diagram of a method for filling a feature with a conductive material, according to embodiments described herein.

FIGS. 4A-4F depict a substrate having an opening into which conductive layers are deposited, according to embodiments described herein.

FIG. 5 illustrates interfaces between a conductive material and a substrate at different biases, according to embodiments described herein.

FIG. 6 illustrates bottom coverage of a trench structure as a function of bias applied to the substrate, according to embodiments described herein.

FIG. 7 illustrates an amount of tungsten remaining in/on a tetraethyl orthosilicate (TEOS) layer as a function of processing temperature and substrate bias, as measured by total reflection X-ray fluorescence (TXRF), according to embodiments described herein.

FIG. 8 illustrates an amount of tungsten remaining in/on a TEOS layer as a function of substrate bias and the presence of an underlayer, as measured by TXRF, according to embodiments described herein.

FIG. 9 illustrates the resistivity of a layer of PVD tungsten deposited at 25° C. and 325 mTorr as a function of substrate bias, according to embodiments described herein.

FIG. 10 illustrates the resistivity of 40 to 50 angstrom PVD tungsten films after 10 seconds of annealing at different temperatures, according to embodiments described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the disclosure provided herein generally relate to physical vapor deposition (PVD) of thin films on substrates having features formed therein by use of an electronic device fabrication process. More particularly, embodiments described herein provide apparatus and methods for improving the electrical characteristics of a conductive feature by reducing intermixing between the conductive feature and an underlying layer (e.g., a dielectric layer) on which the conductive feature is formed.

### Exemplary Substrate Processing System

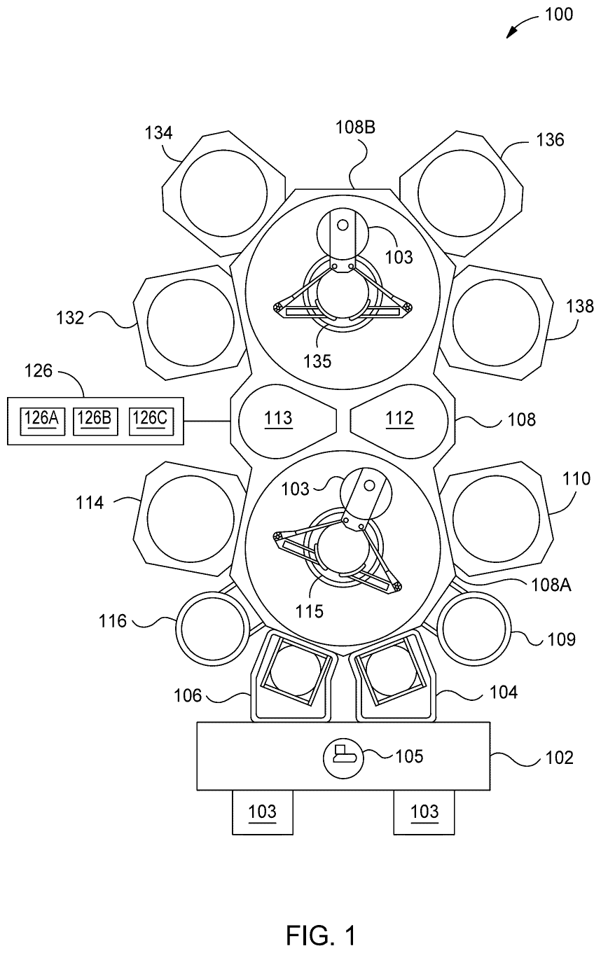

FIG. 1 is a schematic top view of an exemplary substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are a PVD chamber that is configured similar to the processing chamber 200 described below.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the processing system 100 for controlling one or more of the components therein. For example, the system controller 126 may control the operation of the processing chamber 200, which is described further below. In operation, the system controller 126 enables data acquisition and feedback from the respective components to coordinate processing in the processing system 100.

The system controller 126 includes a programmable central processing unit (CPU) 126A, which is operable with a memory 126B (e.g., non-volatile memory) and support circuits 126C. The support circuits 126C (e.g., cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (e.g., non-volatile memory), that when executed by the CPU 126A, facilitates the operation of the processing system 100. The instructions in the memory 126A are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Processing Chamber Example

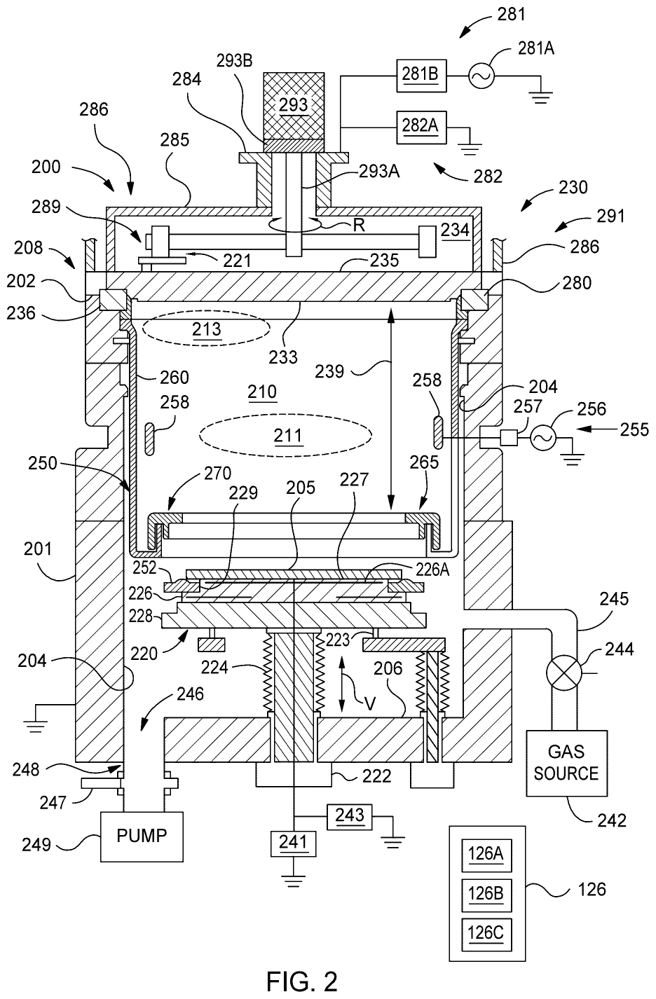

FIG. 2 illustrates an exemplary processing chamber 200 having an upper process assembly 208, a process kit 250, and a substrate support pedestal 220, which are all configured to process a substrate 205 disposed in a central processing region 210. The process kit 250 includes a process kit shield 260, a lower process kit 265, and an isolator ring assembly 280. In the version shown, the processing chamber 200 comprises a sputtering chamber, also called a PVD chamber, capable of depositing a single or multi-compositional material from a target 235 on the substrate 205. The processing chamber 200 may also be used to deposit aluminum, copper, nickel, platinum, hafnium, silver, chrome, gold, molybdenum, silicon, ruthenium, tantalum, tantalum nitride, tantalum carbide, titanium nitride, tungsten, tungsten nitride, lanthanum, alumina, lanthanum oxides, nickel platinum alloys, and titanium, and or combination thereof. Such processing chambers are available from Applied Materials located in Santa Clara, Calif. It is contemplated that other processing chambers including those from other manufacturers may be adapted to benefit from one or more of the embodiments of the disclosure described herein.

The processing chamber 200 includes a chamber body 201 having sidewalls 204, a bottom wall 206, and an upper process assembly 208 that enclose the central processing region 210 or plasma zone. The chamber body 201 is typically fabricated from welded plates of stainless steel or a unitary block of aluminum. In one embodiment, the sidewalls comprise aluminum and the bottom wall comprises stainless steel plate. The sidewalls 204 generally contain a slit valve (not shown) to provide for entry and egress of a substrate 205 from the processing chamber 200. Components in the upper process assembly 208 of the processing chamber 200 in cooperation with the process kit shield 260, substrate support pedestal 220, and cover ring 270 confine the plasma formed in the processing region 210 to the region above the substrate 205.

A substrate support pedestal 220 is supported from the bottom wall 206 of the chamber 200. The substrate support pedestal 220 supports a deposition ring 270 along with the substrate 205 during processing. The substrate support pedestal 220 is coupled to the bottom wall 206 of the chamber 200 by a lift mechanism 222, which is configured to move the substrate support pedestal 220 between an upper processing position and lower transfer position. Additionally, in the lower transfer position, lift pins 223 are moved through the substrate support pedestal 220 to position the substrate a distance from the substrate support pedestal 220 to facilitate the exchange of the substrate with a substrate transfer mechanism disposed exterior to the processing chamber 200, such as a single blade robot (not shown). A bellows 224 is typically disposed between the substrate support pedestal 220 and the chamber bottom wall 206 to isolate the processing region 210 from the interior of the substrate support pedestal 220 and the exterior of the chamber.

The substrate support pedestal 220 generally includes a support 226 sealingly coupled to a platform housing 228. The platform housing 228 is typically fabricated from a metallic material such as stainless steel or aluminum. A cooling plate (not shown) is generally disposed within the platform housing 228 to thermally regulate the support 226.

The support 226 may be comprised of aluminum or ceramic. The substrate support 226 has a substrate receiving surface 227 that receives and supports the substrate 205 during processing, the substrate receiving surface 227 being substantially parallel to a sputtering surface 233 of the target 235. The target 235 and the sputtering surface 233 are separate be a spacing 239. The support 226 also has a peripheral edge 229 that terminates before an overhanging edge of the substrate 205. The support 226 may be an electrostatic chuck, a ceramic body, a heater or a combination thereof. In some embodiments, the support 226 is an electrostatic chuck that includes a dielectric body having a conductive layer, or electrode 226A, embedded therein. The dielectric body is typically fabricated from a high thermal conductivity dielectric material such as pyrolytic boron nitride, aluminum nitride, silicon nitride, alumina or an equivalent material. Other aspects of the substrate support pedestal 220 and support 226 are further described below. In one embodiment, the conductive layer 226A is configured so that when a DC voltage is applied to the conductive layer 226A, by an electrostatic chuck power supply 243, a substrate 205 disposed on the substrate receiving surface 227 will be electrostatically chucked thereto to improve the heat transfer between the substrate 205 and the support 226. In another embodiment, an RF bias power source 241 is also coupled to the conductive layer 226A so that a voltage can be maintained on the substrate during processing to affect the plasma interaction with the surface of the substrate 205.

A program (or computer instructions) readable by the system controller 126 determines which tasks are performable on a substrate. Preferably, the program is software readable by the system controller 126 that includes code to perform tasks relating to monitoring, execution, and control of the movement and various process recipe tasks and recipe steps being performed in the processing system 100 and processing chamber 200. For example, the controller 126 can comprise program code that includes a substrate positioning instruction set to operate the substrate support pedestal 220; a gas flow control instruction set to operate gas flow control valves to set a flow of sputtering gas to the chamber 200; a gas pressure control instruction set to operate a throttle valve or gate valve to maintain a pressure in the chamber 200; a temperature control instruction set to control a temperature control system (not shown) in the substrate support pedestal 220 or sidewalls 204 to set temperatures of the substrate or sidewalls 204, respectively; and a process monitoring instruction set to monitor the process in the chamber 200.

The chamber 200 also contains a process kit 250 which comprises various components that can be easily removed from the chamber 200, for example, to clean sputtering deposits off the component surfaces, replace or repair eroded components, or to adapt the chamber 200 for other processes. In one embodiment, the process kit 250 comprises an isolator ring assembly 280, a process kit shield 260 and a ring assembly 268 for placement about a peripheral edge 229 of the support 226 that terminates before an overhanging edge of the substrate 205.

The upper process assembly 208 may also comprise an RF source 281, a direct current (DC) source 282, an adaptor 202, a motor 293, and a lid assembly 230. The lid assembly 230 generally comprises a target 235, a magnetron system 289 and a lid enclosure 291. The upper process assembly 208 is supported by the sidewalls 204 when in a closed position, as shown in FIG. 2. The adaptor 202 is sealably coupled to the sidewalls 204, and is configured to help with the removal of the upper process assembly 208 and isolator ring assembly 280.

When in the processing position, the target 235 is disposed adjacent to the adaptor 202, and is exposed to the processing region 210 of the processing chamber 200. The target 235 contains material that is deposited on the substrate 205 during a PVD, or sputtering, process. The isolator ring assembly 280 is disposed between the target 235 and the process kit shield 260 and chamber body 201 to electrically isolate the target 235 from the process kit shield 260 and chamber body 201.

During processing, the target 235 is biased relative to a grounded region of the processing chamber (e.g., chamber body 201 and adaptor 202) by a power source disposed in the RF source 281 and/or the direct current (DC) source 282. It is believed that by delivering RF energy and DC power to the target 235 during a high pressure PVD process, significant process advantages can be achieved over conventional low pressure DC plasma processing techniques when used in conjunction with sputtering materials such as tungsten, cobalt, titanium, copper, nickel, ruthenium, aluminum, tantalum, molybdenum, and tungsten to name just a few. Additionally, in one embodiment, the combination of RF and DC power sources allows for a lower overall RF power to be used during processing versus a RF only source, which can help to decrease plasma related damage of the substrate and increase device yield. In one embodiment, the RF source 281 comprises an RF power source 281A and an RF match 281B that are configured to efficiently deliver RF energy to the target 235. In one example, the RF power source 281A is capable of generating RF currents at a frequency of between about 13.56 MHz and about 228 MHz at powers between about 0 and about 8 kWatts. In one example, the DC power supply 282A in the DC source 282 is capable of delivering between about 0 and about 10 kWatts of DC power.

The central portion of the processing chamber 200 includes an inductive coil assembly 255 that is positioned within a central region of the process kit 250, and is configured to form an inductively couple plasma 211 during processing that is used to ionize atoms ejected from the target 235 and/or ionize process gases during processing. The inductive coil assembly 255 includes an RF source 256 and an impedance match 257 that are coupled to a coil 258 that is disposed within the processing region 210 of the processing chamber 200. In some embodiments, the coil 258 includes a single turn coil that is formed from a metal. In one configuration, the coil 258 is formed from a conductive material that is made of the same material as the target 235. In some configurations, the RF power source 256 is capable of generating RF currents at a frequency of between about 13.56 MHz and about 228 MHz at powers between about 0 and about 10 kWatts.

During processing, a gas, such as argon, is supplied to the processing region 210 from a gas source 242 via mass flow controller 244 coupled to a conduits 245. The gas source 242 may comprise a non-reactive gas such as argon, krypton, helium or xenon, which is capable of energetically impinging upon and sputtering material from the target 235. The gas source 242 may also include a reactive gas, such as one or more of an oxygen-containing gas or a nitrogen-containing gas, which is capable of reacting with the sputtering material to form a layer on a substrate. Spent process gas and byproducts are exhausted from the chamber 200 through exhaust ports 246 that receive spent process gas and direct the spent process gas to an exhaust conduit 246 having an adjustable position gate valve 247 to control the pressure in the processing region 210 in the chamber 200. The exhaust conduit 246 is connected to one or more exhaust pump 249, such as a cryopump. Typically, the pressure of the sputtering gas in the chamber 200 during processing is set to sub-atmospheric levels, such as a vacuum environment, for example, a pressure of about 0.6 mTorr to about 400 m Torr. In one embodiment, the processing pressure is set to about 250 mTorr to about 400 mTorr, such as about 325 mTorr. A plasma is formed between the substrate 205 and the target 235 from the gas. Ions within the plasma are accelerated toward the target 235 and cause material to become dislodged from the target 235. The dislodged target material is deposited on the substrate.

The lid enclosure 291 generally comprises a conductive wall 285, a center feed 284 and shielding 286. In this configuration, the source distribution plate 285, the center feed 284, the target 235 and a portion of the motor 293 enclose and form a back region 234. The back region 234 is a sealed region disposed on the back side of the target 235 and is generally filled with a flowing liquid during processing to remove the heat generated at the target 235 during processing. In one embodiment, the conductive wall 285 and center feed 284 are configured to support the motor 293 and magnetron system 289, so that the motor 293 can rotate the magnetron system 289 during processing. In one embodiment the motor 293 is electrically isolated from the RF or DC power delivered from the power supplies by use of a dielectric layer 293B, such as Delrin, G10, or Ardel.

The shielding 286 may comprise one or more dielectric materials that are positioned to enclose and prevent the RF energy delivered to the target 235 from interfering with and affecting other processing chambers disposed in the cluster tool 100 (FIG. 1). In one configuration, the shielding 286 may comprise a Delrin, G10, Ardel or other similar material and/or a thin grounded sheet metal RF shield.

To provide efficient sputtering, a magnetron system 289 is positioned in back of the target 235 in the upper process assembly 208 to create a magnetic field in the processing region 210 adjacent the sputtering surface 233 of the target 235, which creates a magnetron induced plasma 213. The magnetic field by magnetron system 289 is created to trap electrons and ions to thereby increase the plasma density in the magnetron induced plasma 213 region and to thereby also increase the sputtering rate. According to some embodiments, the magnetron system 289 includes a source magnetron assembly 221 that comprises an outer pole (not shown) and an inner pole (not shown). The magnetron system 289 is rotated about the central axis 294 of the chamber 200 by use of the motor 293. In some embodiments, a “closed loop” magnetron configuration is formed within the magnetron system 289 such that the outer pole of the magnetron surrounds the inner pole of the magnetron forming a gap between the poles that is a continuous loop. In the closed loop configuration, the magnetic fields that emerge and reenter through a surface of the target form a “closed loop” pattern can be used to confine electrons near the surface of the target in a closed pattern, which is often called a “racetrack” type pattern. A closed loop, as opposed to the open-loop, magnetron configuration is able to confine electrons and generate a high density plasma near the sputtering surface 233 of the target 235 to increase the sputtering yield. In some other embodiments, an “open loop” magnetron configuration is formed within the magnetron system 289 such that the outer pole of the magnetron surrounds the inner pole of the magnetron forming a gap between the poles that is a continuous loop. In an open loop magnetron configuration, the electrons trapped between the inner and outer poles will migrate, leak out and escape from the B-fields created at open ends of the magnetron, thus only holding the electrons for a short period of time during the sputtering process due to the reduced confinement of the electrons. It has been found that the use of an open loop magnetron configuration, can provide significant step coverage improvements and provide an improved material composition uniformity across the substrate surface, when used in conjunction with the RF and DC sputtering of multi-compositional targets described herein.

In some embodiments of the processing chamber 200, an RF bias power source 241 is coupled between an electrode and RF ground to adjust the bias on the substrate (also referred to as “wafer bias”) during processing to control the degree of bombardment on the substrate surface. In some embodiments, the electrode is disposed adjacent to the substrate receiving surface 227 of a support 226, and comprises the electrode 226A. In a PVD reactor, tuning of the bombardment of the substrate surface by the control of the impedance of the electrode to ground, will affect step coverage, overhang geometry and deposited film's properties, such as grain size, film stress, crystal orientation, film density, roughness and film composition. Therefore, the RF bias power source 241 can thus be used to alter the deposition rate, the etching rate and even the composition of a multi-compositional film at the substrate surface. In some embodiments, the RF bias power source 241 is employed to enable deposition or etching, by the appropriate adjustment of impedance of the electrode/substrate to ground. In some embodiments of the RF bias power source 241, the RF bias power source 241 that has a variable capacitor tuning circuit with a feedback circuit to control the properties of a deposited metal or non-metal layer on a substrate.

In some embodiments, the RF bias power source 241 is replaced by an RF source (not shown) and an impedance match (not shown) that are coupled to the electrode 226A. In some embodiments, the RF power source is capable of generating RF currents at a frequency of between about 13.56 MHz and about 228 MHz at powers between about 0 and about 10 kWatts.

### Processing Methods

Conductive features grown via physical vapor deposition (PVD) techniques, such as tungsten capping and liner processes, are foundational to minimizing contact resistance in middle-of-line (MOL) process steps. Existing tungsten capping and liner processes include PVD tungsten deposition, tungsten wet etch removal, and chemical vapor deposition (CVD) deposition of tungsten to either selectively deposit tungsten bottom-up, or to conformally fill a MOL structure, such as a trench associated with a gate, a contact pad, a conductive line, via, etc. Achieving high bottom coverage with minimal overhang is a prerequisite to achieving good gap fill for a bottom-up deposition approach.

Existing approaches have a number of drawbacks. For example, the application of a bias to a substrate during sputtering can effectively increase sheath voltage, causing resputtering of materials. Because the substrate is typically positioned close to a target during sputtering, material ejected from the target travels towards the substrate at a large incident angle, causing a disproportionate amount of material to accumulate on the edges of an opening (e.g., a trench) into which the material is being deposited. This accumulation of excess material creates overhang, which may result in bottom coverage reduction or pinch-off. Additionally, the high temperatures and/or high substrate biases implemented during PVD deposition of metal, such as tungsten, molybdenum, cobalt, titanium, tantalum, ruthenium or other similar metal, results in penetration of metal into the exposed surface of a substrate onto which it is deposited. Typical substrate surfaces include a dielectric layer, which can include silicon dioxide (SiO₂), silicon nitride (SiN), a low-k dielectric, ultra-low-k dielectric or other similar material. Consequently, after pullback (or a similar etching process), metal (e.g., tungsten) remains intermixed with a portion of the substrate surface, resulting in interface scattering in the intermixed portion when a current is driven through the metal layer formed on the substrate during device operation. The creation of interface scattering within the metal layer increases the resistivity of conductive features formed on the substrate during device operation.

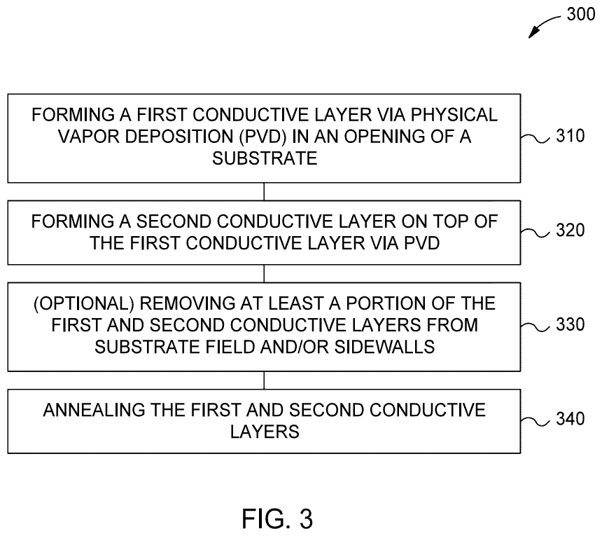

In various embodiments, the processing techniques disclosed herein may be implemented to reduce overhang and improve bottom coverage of a deposited metal layer on the substrate by increasing the spacing between the target and the substrate. For example, at low processing pressures, increasing the spacing between the target and the substrate lowers the incident angle at which material ejected from the target travels towards the substrate, resulting in a higher percentage of the material reaching the bottom surface of an opening (e.g., a trench) formed in the substrate, and reducing the percentage of material that is deposited on the edges of the opening. At high processing pressures, increasing the spacing between the target and the substrate may increase the Penning ionization rate (e.g., due to a higher number of collisions between atoms or molecules in a gas) resulting in a higher metastable ion fraction that is affected by the substrate bias, which may reduce the percentage of material that is deposited on the edges of the opening. Additionally, by decreasing the temperature at which the PVD deposited metal layers are deposited (e.g., to room temperature) and/or decreasing the bias applied to the substrate (e.g., to 0 V), the kinetic energy of material deposited onto the substrate is lower, reducing the degree to which the deposited material intermixes with the surface of the substrate. In various embodiments, a low-energy conductive underlayer may be deposited via PVD at a low temperature and low substrate bias, followed by deposition of a thicker conductive layer at a higher substrate bias. By first depositing a low-energy conductive underlayer, intermixing between the conductive layer and the substrate is reduced, resulting in a smoother boundary that reduces interface scattering and resistivity of associated conductive feature(s). Such techniques are described below in further detail in conjunction with FIGS. 3, 4A-4F, and 5-10.

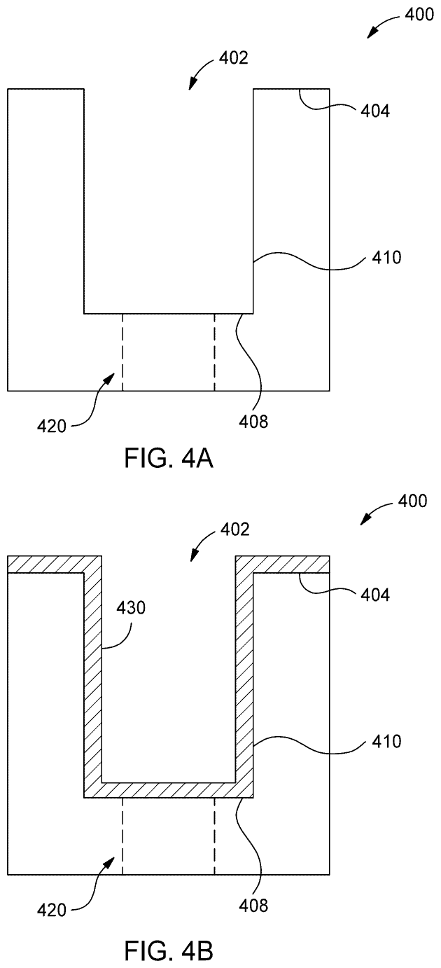

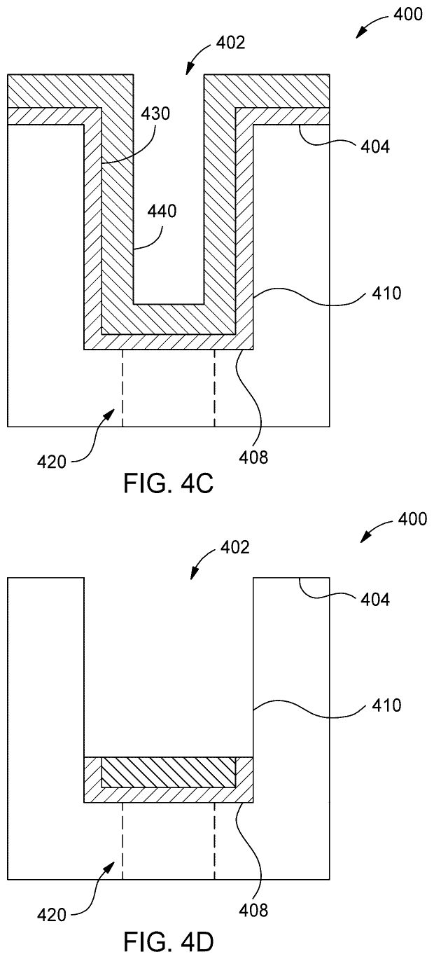

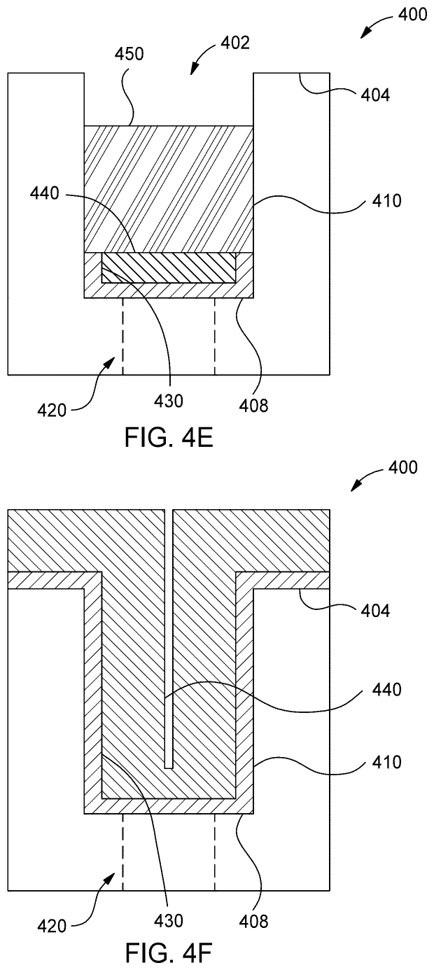

FIG. 3 depicts a flow diagram of a method 300 for filling a feature with a conductive material, according to embodiments described herein. The method 300 is described below with respect to an opening 402 formed in a substrate 400, as depicted in FIGS. 4A-4F. The method 300 may be performed in any suitable process chambers configured for one or more of chemical vapor deposition (CVD), physical vapor deposition (PVD), or atomic layer deposition (ALD). Exemplary processing systems suitable for use to perform the inventive methods disclosed herein may include, but are not limited to, any of the ENDURA®, CENTURA®, or PRODUCER® line of processing systems, and the ALPS® Plus or SIP ENCORE® PVD process chambers, all commercially available from Applied Materials, Inc., of Santa Clara, Calif. Other process chambers, including ones available from other manufacturers, may also be suitably used in connection with the teachings provided herein. In some embodiments, depositing one or more layers of conductive material via a physical vapor deposition (PVD) process may be performed in a deposition (PVD) processing system such as processing chamber 200 depicted in FIG. 2.

In some embodiments, the method 300 may begin by providing a substrate 400 (shown in FIGS. 4A-4F) to a PVD process chamber, for example the processing chamber 200 shown in FIG. 2. The processing chamber 200 includes a substrate support pedestal 220 for receiving a substrate 400 thereon, and a sputtering source, such as a target 235. In some embodiments, the target 235 is configured, as is known in the art, and may include one or more metals (e.g., tungsten or tungsten source materials) as described herein. Although the method 300 is described in conjunction with tungsten, in various embodiments, the target(s) and source materials may include, for example, and without limitation, one or more of tungsten, cobalt, titanium, copper, nickel, ruthenium, aluminum, tantalum, molybdenum, etc.

FIG. 4A depicts the substrate 400, which has an opening 402 formed in a first surface 404 (also referred to as the substrate field) of the substrate 400 and extending into the substrate 400 along sidewalls 410 and towards a bottom surface 408 of the substrate 400. The substrate 400 may include one or more of a dielectric material, silicon (Si), metals, or the like. In addition, the substrate 200 may include additional layers of materials or may have one or more completed or partially completed structures formed in, or on, the substrate 400. For example, the substrate 400 may include a dielectric layer, such as silicon oxide, a low-k material (e.g., a material having a dielectric constant less than silicon oxide, or less than about 3.9), or the like. The opening 402 may be formed in the dielectric layer. A conductive feature 420 (illustrated by dotted lines) may be disposed at the bottom surface 408 of the opening 402 and may be at least partially aligned with the opening 402. In some embodiments, the opening 402, when filled with a conductive material such as tungsten, provides an electrical path to and from the conductive feature 420, for example, as part of a device (e.g., a logic device), an electrical path to a device (e.g., a gate, a contact pad, a conductive line, via), or the like.

The opening 402 may be any opening, such as a trench, via, dual damascene structure, or the like. In some embodiments, the opening 402 may have a height to width aspect ratio of about 4:1 or more such as 4:1 to 9:1, or 4:1 to 20:1 (e.g., a high aspect ratio). In some embodiments, opening 402 is a trench or via having a diameter of 25 nm or less, for example about 1 nm to about 25 nm, such as 20 nm, 14 nm, 7 nm, 5 nm, 3 nm, or 1 nm. The opening 402 may be formed by etching the substrate 400 using any suitable etch process.

Referring back to FIG. 3, at block 310, a first conductive layer 430 (also referred to herein as underlayer 430) is formed in the opening 402 of the substrate 400, as shown in FIG. 4B. The underlayer 430 may be formed by depositing a conductive material (e.g., tungsten, cobalt, titanium, copper, nickel, ruthenium, aluminum, tantalum, molybdenum) via a PVD process performed in a PVD chamber, such as processing chamber 200. In various embodiments, the underlayer 430 is a low-energy layer that may be deposited with a thickness of about 8 angstroms (Å) (e.g., two monolayers of tungsten) at or near room temperature (e.g., approximately 25° C.) with a low or zero bias applied to the substrate 400. For example, in some embodiments, an underlayer 430 having a thickness of about 4 angstroms to about 50 angstroms, such as about 4 angstroms to about 20 angstroms, such as about 4 angstroms to 12 angstroms, such as about 8 angstroms, may be deposited in the opening 402, at a bias of about 0 Watts (W) to about 50 W, such as about 0 W to about 25 W, such as about 1 W to about 50 W, such as about 1 W to about 25 W, applied to the substrate 400, and at a processing temperature of about 10° C. to about 100° C., such as about 15° C. to 40° C., such as about 25° C. In some embodiments, the processing pressure is set to about 250 mTorr to about 400 m Torr, such as about 325 mTorr, and a spacing 239 between the target 235 and the substrate 400 may be about 50 mm to about 250 mm, such as about 80 mm to about 200 mm, such as about 130 mm to about 160 mm. Increasing the spacing 239 between the target 235 and the substrate 400 may enable more uniform distribution of the sputtering gas (e.g., argon) within the processing chamber. Additionally, increasing the spacing 239 between the target 235 and the substrate 400 may reduce the incident angle at which material ejected from the target travels towards the opening 402, reducing overhang that can form at the edges of the opening 402 and improving bottom coverage of the deposited material within the opening 402.

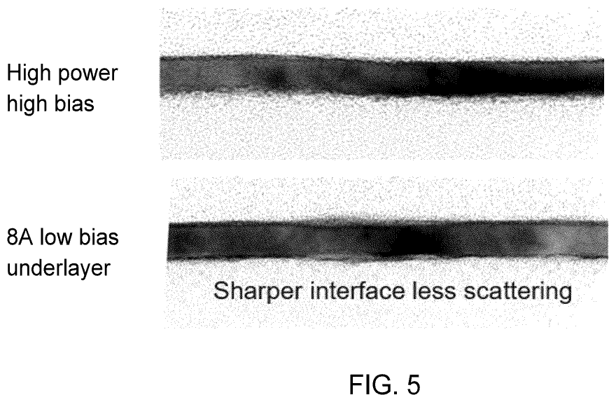

Depositing a low-energy underlayer 430 at low temperature and/or at a low or zero bias applied to the substrate 400 reduces intermixing of the deposited layer within the material disposed at the surface of the substrate and creates a smooth boundary between the conductive material and the substrate 400, as shown in FIG. 5. This smooth boundary may reduce scattering of electrons at one or more interfaces formed between the substrate 400 and the underlayer 430, decreasing the resistivity of the formed metal layer and improving performance of any devices and/or electrical paths that are electrically coupled to conductive feature 420. For example, depositing the underlayer 430 at low energy is believed to promote the growth of the alpha phase of tungsten, which has lower resistivity than the beta phase of tungsten. By contrast, when depositing tungsten (or similar materials) at a higher substrate bias, the additional kinetic energy may be sufficient to overcome an energy barrier associated with forming the beta phase, resulting in the more brittle, higher-resistivity beta phase being deposited onto the substrate. Additionally, because tungsten is a heavy element, a relatively thin layer (e.g., 4 to 12 angstroms, such as about 8 angstroms or about two monolayers) is believed to provide sufficient protection against intermixing during subsequent, higher-energy deposition processes.

Next, at block 320, a second conductive layer 440 is formed on the first conductive layer 430 (also referred to as the underlayer 430), as shown in FIG. 4C. The second conductive layer 440 may be formed by depositing a conductive material (e.g., tungsten, cobalt, titanium, copper, nickel, ruthenium, aluminum, tantalum, molybdenum) via a PVD process performed in a PVD chamber, such as processing chamber 200. In various embodiments, the second conductive layer 440 may be deposited with a thickness of about 40 angstroms at or near room temperature (e.g., approximately 25° C.) with a bias of about 150 W applied to the substrate 400. For example, in some embodiments, a second conductive layer 440 having a thickness of about 20 angstroms to about 100 angstroms, such as about 30 angstroms to about 60 angstroms, such as about 35 angstroms to 45 angstroms, such as about 40 angstroms, may be deposited on underlayer 430, at a bias of about 0 W to about 350 W, such as about 125 W to about 175 W, such as about 150 W, applied to the substrate 400, and at a processing temperature of about 10° C. to about 100° C., such as about 15° C. to 40° C., such as about 25° C. In some embodiments, the processing pressure is set to about 250 mTorr to about 400 mTorr, such as about 325 mTorr, and a spacing 239 between the target 235 and the substrate 400 may be about 50 mm to about 250 mm, such as about 80 mm to about 200 mm, such as about 130 mm to about 160 mm, such as about 145 mm. In general, depositing the second conductive layer 440 at a higher substrate bias (e.g., relative to the first conductive layer 430) results in the formation the beta phase of the conductive material. As further described below, this beta phase may be converted to the alpha phase by annealing the first and second conductive layers 430, 440.

At block 330, at least a portion of the first conductive layer 430 and the second conductive layer 440 are optionally removed from the opening 402. For example, as shown in FIG. 4D, a “pullback” process (e.g., including one or more wet etch steps) may be performed to remove at least a portion of the first conductive layer 430 and the second conductive layer 440 from the first surface 404 and sidewalls 410 of the substrate 400 and opening 402.

At block 340, the substrate 400 may be annealed. As described above, annealing may be performed to convert the beta phase of the conductive material (e.g., tungsten, cobalt, titanium, copper, nickel, ruthenium, aluminum, tantalum, molybdenum) included in the second conductive layer 440 into the alpha phase, which has a lower resistivity than the beta phase. Annealing may be performed at a temperature of about 150° C. to about 350° C., such as about 200° C. to about 250° C. for about 5 seconds to about 30 seconds, such as about 10 seconds.

In some embodiments, annealing may be performed at block 340 during a selective chemical vapor deposition (CVD) process that deposits a bulk layer 450 of conductive material (e.g., tungsten, cobalt, titanium, copper, nickel, ruthenium, aluminum, tantalum, molybdenum) in the opening 402 during a “capping” process, as shown in FIG. 4E. For example, tungsten hexafluoride (WF₆) (or any other suitable precursor gas for depositing, for example, tungsten, cobalt, titanium, copper, nickel, ruthenium, aluminum, tantalum, or molybdenum) may be introduced to the processing chamber in order to deposit tungsten in the opening 402. Because the CVD capping process is performed at a temperature of about 250° C. to about 350° C., such as about 300° C., the first conductive layer 430 and second conductive layer 440 are annealed during the CVD process, without requiring a separate, dedicated anneal step.

In some embodiments, after block 320, instead of removing the first conductive layer 430 and second conductive layer 440 from the opening 402, method 300 may proceed to block 340, where the first conductive layer 430 and second conductive layer 440 are annealed while also performing a CVD “liner” process that deposits additional conductive material to fill the opening 402, as shown in FIG. 4F. For example, additional conductive material may be deposited via a CVD process at a temperature of about 250° C. to about 350° C., such as about 300° C., to bulk fill high-aspect ratio features (e.g., opening 402) formed in the substrate 400. Such CVD processes may utilize the first conductive layer 430 and/or second conductive 440 as nucleation layers on which additional conductive material is deposited during the bulk fill step.

Advantageously, the CVD techniques described above (or any other high-temperature process that may be performed after the first conductive layer 430 and/or second conductive layer 440 are deposited via PVD) obviates the need for a separate annealing step, since the CVD process is performed at a sufficiently high temperature and for sufficient period of time to convert beta phase conductive material to the lower-resistivity alpha phase. Accordingly, substrate processing time and overall energy usage may be decreased.

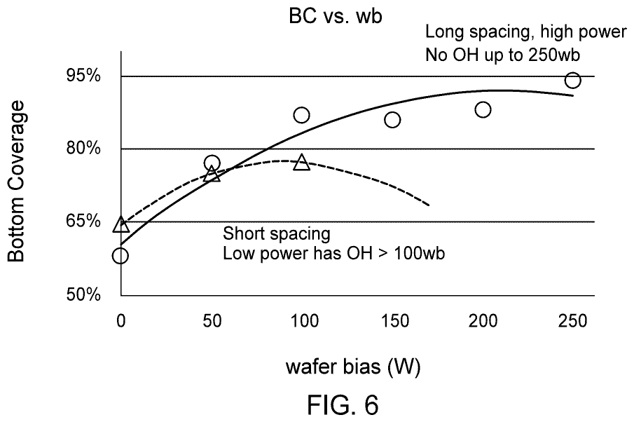

FIG. 6 illustrates bottom coverage of a trench structure as a function of bias applied to the substrate 400, according to embodiments described herein. As shown, increasing the spacing 239 between the target 235 and the substrate 400 from 95 mm to 145 mm significantly improves bottom coverage, from less than 80% to greater than 90%, at non-zero substrate biases. One potential mechanism for this improvement in bottom coverage is a reduction in the angle at which sputtered material travels towards the opening 402, due to the additional distance between the target 235 and the substrate 400. This reduction in the incident angle reduces overhang at edges of the opening 402, enabling more sputtered material to reach the bottom surface 408 of the opening 402, thereby improving bottom coverage.

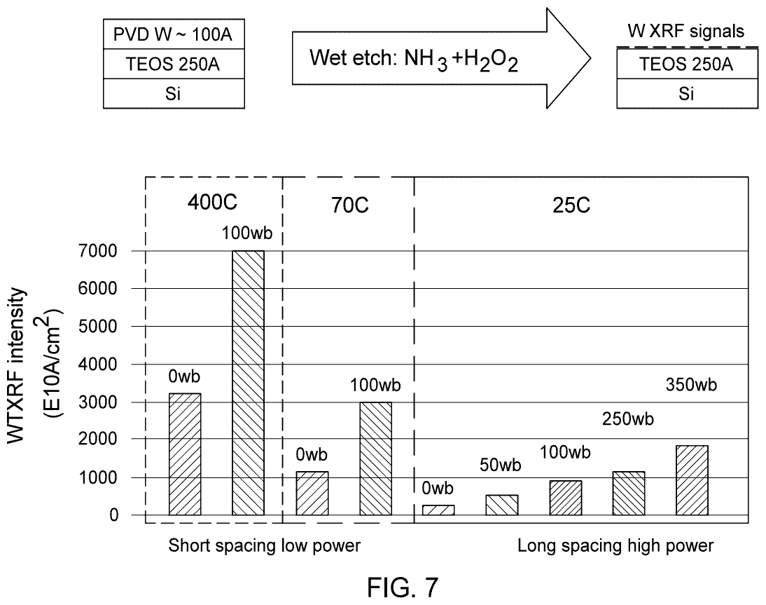

FIG. 7 illustrates an amount of tungsten remaining in/on a tetraethyl orthosilicate (TEOS) layer as a function of processing temperature and substrate bias, as measured by total reflection X-ray fluorescence (TXRF), according to embodiments described herein. As shown, a 100-angstrom layer of PVD tungsten was deposited at three temperatures (e.g., 400° C., 70° C., and 25° C.) and at different spacings 239 and substrate biases (e.g., 0 W, 50 W, 100 W, 250 W, 350 W), resulting in different amounts of intermixing between the tungsten and TEOS layers. As a result, after wet etching the tungsten layer, different amounts of tungsten remained in/on the TEOS substrate, as shown in FIG. 7, where an increase in TXRF intensity indicates an increase in the amount of remaining tungsten.

In general, at a processing temperature of 400° C., the TXRF signal is very high. Additionally, when the substrate bias is increased, then the energy applied to the tungsten increases, causing more intermix and resulting in more tungsten remaining in/on the TEOS layer. Lowering the processing temperature and using longer spacing 239 (e.g., about 145 mm) results in almost no intermixing of tungsten with the dielectric layer (e.g., TEOS).

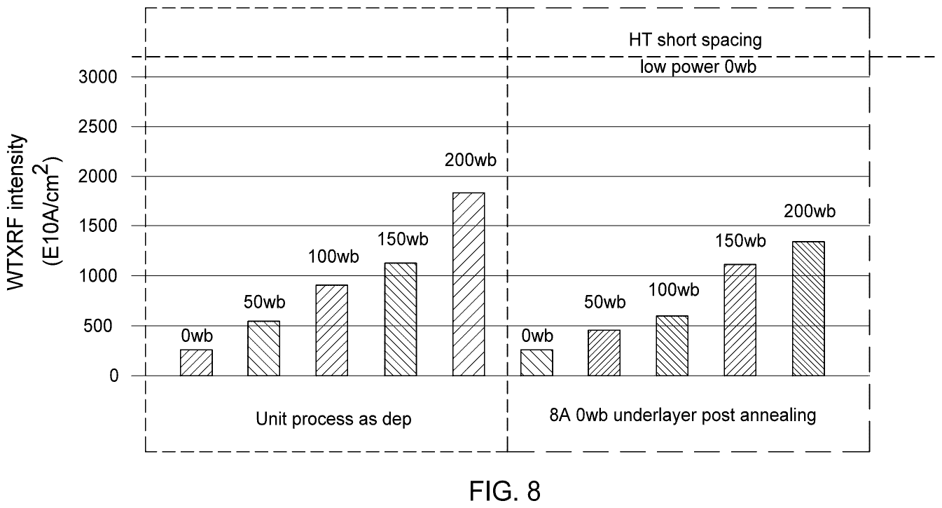

FIG. 8 illustrates an amount of tungsten remaining in/on a TEOS layer as a function of substrate bias and the presence of an underlayer 430, as measured by TXRF, according to embodiments described herein. A 100-angstrom layer of PVD tungsten was deposited at different substrate biases (e.g., 0 W, 50 W, 100 W, 250 W, 350 W), both with (right) and without (left) an 8-angstrom underlayer 430, resulting in different amounts of intermixing between the tungsten and TEOS layers. After wet etching the tungsten layer, less tungsten remained in/on the TEOS substrate when the 100-angstrom layer of PVD tungsten was deposited on top of an 8-angstrom underlayer 430, as compared to the TEOS substrates that did not include an underlayer 430. Advantageously, using a low-energy underlayer 430 can effectively cancel out the negative effects of intermixing (e.g., an increase in resistivity) that occur during post annealing, resulting in a final TXRF signal comparable with an as-deposited tungsten layer. Notably, all room temperature deposition processes-both with and without the use of an underlayer 430—performed significantly better than depositing 100-angstrom tungsten layer at a high temperature (250° C.) and with a short spacing 239 of 95 mm (top line in FIG. 8).

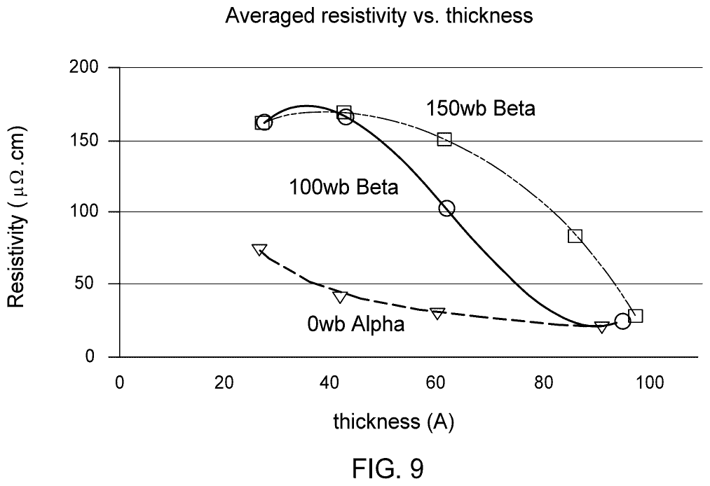

FIG. 9 illustrates the resistivity of a layer of PVD tungsten deposited at 25° C. and 325 mTorr as a function of substrate bias, according to embodiments described herein. As shown, tungsten deposited at a substrate bias of 0 W resulted in more alpha phase, significantly reducing resistivity at lower thicknesses. By contrast, depositing tungsten at a substrate bias of 100 W or 150 W resulted in more beta phase and a higher corresponding resistivity at lower thicknesses. As described above, one potential explanation for the differences in phase and resistivity may be related to the energy applied to tungsten during deposition; at lower energies, alpha phase is grown, while adding a bias to the substrate increases the kinetic energy of the ions, enabling the deposited tungsten to overcome an energy barrier, resulting in more beta phase and a higher resistivity.

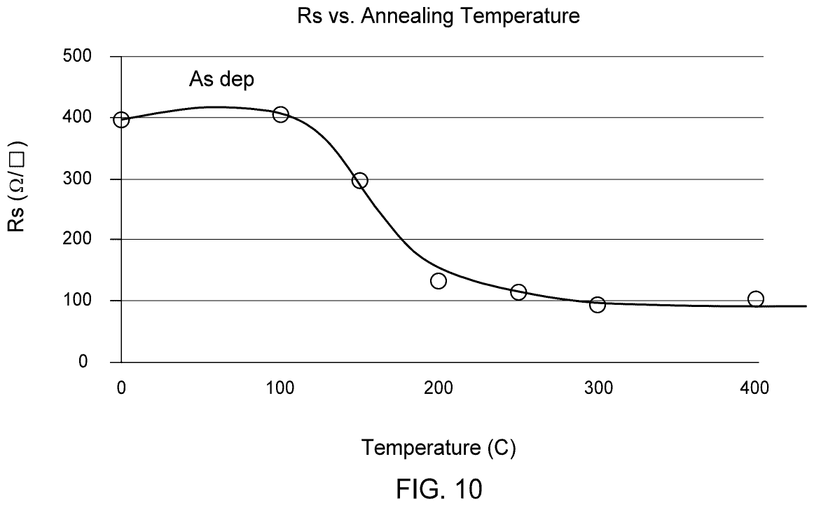

Additionally, as shown in FIG. 9, the curves associated with a substrate bias of 100 W and 150 W exhibit a dome shape. This behavior may be explained by changes that occur in deposited material as layer thickness increases. For example, as the thickness of the tungsten layer increases (e.g., from about 20 to about 40 angstroms), the number of alpha phase puddles (e.g., which merge from the beta phase grain) increases, causing more grain boundary scattering (also referred to as interface scattering). However, once the tungsten layer grows thicker (e.g., greater than about 40 angstroms), stress builds up in the layer, causing the meta-stable beta phase to undergo a transition to the alpha phase, lowering the resistivity of the layer. Advantageously, as described above, this beta phase to alpha phase transition can also occur as a result of thermal annealing. For example, as shown in FIG. 10, which illustrates the resistivity of 40 to 50 angstrom PVD tungsten films after 10 seconds of annealing at different temperatures, resistivity can be significantly reduced as compared to an as-deposited layer, by performing a short annealing step (e.g., during a CVD process or during a separate, dedicated thermal annealing step).

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
forming a first conductive layer via physical vapor deposition (PVD) in an opening of a substrate, wherein the first conductive layer has a thickness of less than 20 angstroms;
forming a second conductive layer via PVD on the first conductive layer, wherein the first conductive layer and the second conductive layer are formed at a temperature of less than 50° C.; and
annealing at least a portion of the first conductive layer and the second conductive layer.

2. The method of claim 1, wherein the first conductive layer has a thickness of 4 to 12 angstroms.

3. The method of claim 1, wherein the first conductive layer has a thickness of about 8 angstroms.

4. The method of claim 1, wherein the first conductive layer has a thickness of about two monolayers.

5. The method of claim 1, wherein the first conductive layer and the second conductive layer comprise at least one of tungsten, cobalt, titanium, copper, nickel, ruthenium, aluminum, tantalum, molybdenum.

6. The method of claim 1, wherein the first conductive layer and the second conductive layer comprise tungsten.

7. The method of claim 1, wherein the first conductive layer and the second conductive layer are formed at a temperature of 15° C. to 40° C.

8. The method of claim 1, wherein the first conductive layer and the second conductive layer are formed at about 25° C.

9. The method of claim 1, wherein the first conductive layer is formed with a bias of between 1 W and 50 W applied to the substrate, and the second conductive layer is formed with a bias of greater than 50 W applied to the substrate.

10. The method of claim 1, wherein the first conductive layer is formed with a bias of about 0 W applied to the substrate, and the second conductive layer is formed with a bias of 125 W to 175 W applied to the substrate.

11. The method of claim 1, wherein a spacing between a sputtering target and the substrate is from 130 mm to 160 mm when forming the first conductive layer and the second conductive layer.

12. The method of claim 1, wherein the annealing is performed while forming, via chemical vapor deposition (CVD), a third conductive layer on the second conductive layer.

13. The method of claim 1, further comprising:
etching at least a portion of the first conductive layer and the second conductive layer from one or more sidewalls of the opening; and
after etching, selectively forming a bulk layer of a conductive material on the second conductive layer.

14. A method, comprising:
forming a first conductive layer via physical vapor deposition (PVD) in an opening of a substrate, wherein the first conductive layer has a thickness of less than 20 angstroms;
forming a second conductive layer via PVD on the first conductive layer, wherein the second conductive layer has a thickness of greater than 20 angstroms, and the first conductive layer and the second conductive layer are formed at a temperature of less than 50° C.

15. The method of claim 14, wherein the first conductive layer is formed with a bias of between 1 W and 50 W applied to the substrate, and the second conductive layer is formed with a bias of greater than 50 W applied to the substrate.

16. The method of claim 14, wherein the first conductive layer has a thickness of 4 to 12 angstroms.

17. The method of claim 14, wherein the first conductive layer and the second conductive layer comprise at least one of tungsten, cobalt, titanium, copper, nickel, ruthenium, aluminum, tantalum, molybdenum.

18. A method, comprising:
forming a first conductive layer via physical vapor deposition (PVD) in an opening of a substrate, wherein the first conductive layer has a thickness of less than 20 angstroms;
forming a second conductive layer via PVD on the first conductive layer, wherein the first conductive layer and the second conductive layer are formed at a temperature of less than 50° C.; and
depositing a third conductive layer via chemical vapor deposition (CVD) on the second conductive layer.

19. The method of claim 18, wherein the first conductive layer is formed with a bias of less than 50 W applied to the substrate, and the second conductive layer is formed with a bias of greater than 50 W applied to the substrate.

20. The method of claim 18, wherein the first conductive layer has a thickness of 4 to 12 angstroms.
